(19) United States
(12) Patent Application Publication
(10) Pub. No.: US 2013/0099330 A1
(43) Pub. Date: Apr. 25, 2013

(54) Controllable Undercut Etching of Tin Metal Gate Using DSP+

(71) Applicant: John Foster, (US)

(72) Inventor: John Foster, (US)

(73) Assignee: INTERMOLECULAR, INC., San Jose, CA (US)

(21) Appl. No.: 13/280,900

(22) Filed: Oct. 25, 2011

(51) Int. Cl. H01L 29/78; H01L 21/28

(52) U.S. Cl. 257/412; 438/592; 257/E21.19; 257/E29.255

(57) ABSTRACT

A wet process utilizing a dilute acid oxidant solution, for example, a dilute sulfuric acid with hydrogen peroxide is used in the fabrication of a metal gate electrode of a semiconductor device, offering high etch selectivity and high controllability to achieve a desired profile for the metal gate electrode. In some embodiments, the dilute acid oxidant solution is a dilute sulfuric peroxide solution, comprising at least 50% or 80% by weight of water, less than 30% or 15% by weight of sulfuric acid, and less than 20% or 20% of hydrogen peroxide with optionally less than 100 ppm or 30 ppm ozone. In some embodiments, the dilute sulfuric peroxide solution further comprises less than 100 ppm of hydrofluoric acid. The dilute acid oxidant solution can be used effectively to clean the metal gate electrode or to form an undercut on a metal gate layer of the metal gate electrode.

### FIELD OF THE INVENTION

The present invention relates generally to metal gate devices and the fabrication process of such devices, and particularly to a wet processing of metal gate devices using a dilute acid oxidant solution.

### BACKGROUND OF THE INVENTION

Metal gate electrode has been used for advanced semiconductor devices to address new requirements, including high conductivity to minimize delays due to interconnections between devices, tunable work function to allow n and p-type devices to operate in surface channel mode with minimal gate depletion effects.

The introduction of metal elements to the device, e.g., in the formation of the metal gate electrode, can impose significant changes to the device fabrication process, including device structure designs to reduce leakage, process chemistry to pattern metallic structures and avoid metal corrosion, and cleaning chemistry to remove metallic-containing residues.

Further, advanced semiconductor devices also uses advanced gate dielectric in addition to the metal gate electrode. The advanced gate dielectric can comprise ultra-thin silicon dioxide, for example, less than 5 nm thick, which poses tunneling problems. The advanced gate dielectric can comprise a high-k material, which imposes additional challenges to the device fabrication process. For example, in some portions of the fabrication, etch processes with very high selectivity chemistries and conditions are needed, for example, to avoid gate dielectric punch through or to avoid damage to the device, such as corner damage to the metal gate structure.

### SUMMARY OF THE DESCRIPTION

The present invention relates to metal gate devices, and the fabrication process of such devices, comprising a wet processing using a dilute acid oxidant solution, for example, a dilute sulfuric acid with hydrogen peroxide. In some embodiments, the dilute acid oxidant solution comprises at least 50% by weight of water, preferably deionized water, and more preferably comprises at least 80% by weight of water. The acid component can be any acid, and preferably sulfuric acid. The dilute acid oxidant solution can comprise less than 30% by weight acid, and more preferably less than 15%. The oxidant component can be a liquid oxidant, such as a hydrogen peroxide solution, or a dissolved gaseous oxidant, such as ozone, or a combination of different oxidants. The hydrogen peroxide oxidant is preferably less than 20% by weight of the solution, and more preferably less than 10%. The ozone oxidant is preferably less than 100 ppm, and more preferably less than 30 ppm. Both oxidants of hydrogen peroxide and ozone can be included. In some embodiments, the dilute acid oxidant solution further comprises hydrofluoric acid, preferably at less than 100 ppm. In some embodiments, the present invention discloses a wet process, using a dilute acid oxidant solution, in the fabrication of a metal gate electrode of a semiconductor device.

In some embodiments, the wet process utilizes the dilute acid oxidant solution for selectively etching of two different materials, removing a first material without or with minimum effect on a second material. The dilute acid oxidant solution can comprise at least 50% or 80% by weight of water, less than 30% or 15% by weight of sulfuric acid, and less than 20% or 30% of hydrogen peroxide with optionally less than 100 ppm or 30 ppm ozone. In some embodiments, the dilute acid oxidant solution further comprises less than 100 ppm of hydrofluoric acid. In some embodiments, the first material comprises a metal, such as titanium nitride, tungsten, or aluminum, and the second material comprises a semiconductor material, such as polycrystalline silicon or germanium, an oxide, such as silicon dioxide or a high-k oxide, a dielectric, such as a high-k dielectric. In some embodiments, the first and second materials are incorporated in different layers of a metal gate electrode of a semiconductor device. For example, a metal-containing layer, such as a TiN layer, in a metal gate electrode can comprise the first material. A gate dielectric layer or a gate conductor layer can comprise the second material of silicon dioxide, high-k dielectric; or doped poly silicon, silicide, respectively. The wet process thus comprises selective etching of a metal-containing layer in a metal gate electrode with respect to at least one of the remaining layers, such as a gate dielectric layer or a gate conductor layer.

In some embodiments, the first material comprises a titanium nitride, and the second material comprises a metal, such as titanium, tantalum, tungsten, or aluminum. The TiN material can form a metal-containing layer in a metal gate electrode. Other layers of the metal gate electrode can comprise the metal, for example, the gate conduction layer. The wet process thus comprises selective etching of TiN layer with respect to at least one of the remaining metal-containing layers.

In some embodiments, the first material comprises a polymer, such as an organic polymer, and the second material comprises a semiconductor material, an oxide, a dielectric, a metal, or a silicide. The second material can be components of the layers of the metal gate electrode, and the first material can be generated during the formation, for example, reactive ion etching, of the metal gate electrode. The wet process thus comprises selective etching of the generated polymer, without or with minimum damage to the metal gate electrode.

In some embodiments, the present invention discloses methods and devices fabricated from the methods, for wet processing, using a dilute acid oxidant solution in the fabrication of a metal gate electrode of a semiconductor device. The wet process utilizes the dilute acid oxidant solution for forming an undercut of a metal-containing layer in a metal gate electrode with respect to at least one of the remaining layers, which can be achieved by a selective etching of the metal-containing layer. The dilute acid oxidant solution can comprise at least 50% or 80% by weight of water, less than 30% or 15% by weight of sulfuric acid, and less than 20% or 30% by weight of hydrogen peroxide with optionally less than 100 ppm or 30 ppm ozone. In some embodiments, the dilute acid oxidant solution further comprises less than 100 ppm of HF.

In some embodiments, the metal gate electrode of a semiconductor device comprises a metal-containing layer and a gate dielectric layer, together with other optional layers such as a gate conductor layer. The metal-containing layer can be a TiN layer, or can comprise other metal such as titanium, tantalum, tungsten, or aluminum. The gate dielectric layer can comprise a dielectric layer, such as a high-k layer, or an oxide layer, such as a silicon dioxide. The gate conductor layer can comprise a conducting material, such as a doped poly silicon or germanium layer, a silicide layer such as nickel silicide, titanium silicide or tungsten silicide, or a metal layer, such as titanium, tantalum, tungsten, or aluminum.

The present dilute acid oxidant solution can selectively etch the metal-containing layer of the metal gate electrode to form an undercut with respect to at least a remaining layer of the metal gate electrode, such as the gate conductor layer, or a combination of both gate conductor layer and gate dielectric layer. In some embodiments, gate dielectric layer can also be etched, in addition to the metal-containing layer. The undercut of the metal-containing layer, and optionally the gate dielectric layer, can reduce the vertical electric field between the metal gate electrode and the portion of the source and drain of the semiconductor device that extends under the gate dielectric layer, which then can reduce the leakage current of the semiconductor device.

In some embodiments, the selective etching process can be controlled to achieve a desired profile of the undercut, for example, to optimize a device performance of the semiconductor device, such as minimize a device leakage current. The desired profile of the undercut can comprise a straight recess of the metal-containing layer.

In some embodiments, the present invention discloses methods and devices fabricated from the methods, for cleaning, using a dilute acid oxidant solution, a metal gate electrode of a semiconductor device. The cleaning process utilizes the dilute acid oxidant solution for selectively etching polymer, such as organic polymer, formed on a sidewall of the metal gate electrode during a patterning step, such as a reactive ion etching step to form the metal gate electrode. The selective cleaning process can be achieved by a higher etch rate of the polymer by the dilute acid oxidant solution as compared to the etch rate of the metal gate electrode.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a metal gate electrode device.

FIGS. 2A-2D illustrates a fabrication sequence for a metal gate electrode.

FIGS. 3A-3B illustrate metal gate electrode devices having an undercut profile.

FIGS. 4A-4C illustrate an exemplary fabrication sequence for a metal gate with undercut.

FIGS. 5A-5C illustrate an exemplary sequence for a metal gate with undercut.

FIG. 6 illustrates a schematic representation of exemplary contaminants on a metal gate electrode after a plasma etch process.

FIG. 7 illustrates an exemplary process flow for a selective etching process.

FIG. 8A illustrates an exemplary process flow for cleaning a metal gate electrode.

FIG. 8B illustrates an exemplary process flow for selective etching a metal gate electrode.

FIG. 9 illustrates an exemplary process flow for wet etching a metal gate electrode.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The present invention provides structures and methods for patterning a metal gate electrode, for fabricating semiconductor devices and integrated circuits including the same. The methods for patterning the metal gate electrode comprise forming a metal-containing layer over a gate dielectric layer, and patterning the metal gate electrode using a wet etch process comprising a dilute acid oxidant solution.

With the reduction of gate stack lateral and thickness dimensions, poly silicon gates can deteriorate the performance characteristics of the device, for example, by a depletion effect of charge carriers at the interface of poly silicon electrode and gate dielectric in inversion modes. The depletion can limit further scaling of silicon semiconductor devices.

Metal gate electrode can offer more charge carriers than doped poly silicon, and during inversion, there can be no substantial depletion of charge carriers. Various metal gates electrode structures can be used, for example, a lower metal layer and an upper poly silicon layer, or a lower first metal layer and an upper second metal layer.

In some embodiments, the present invention discloses a wet etch process for the fabrication of a metal gate electrode, and for integrating the fabrication of metal gate electrodes into existing of semiconductor device manufacturing processes. The present wet etch process utilizes a dilute acid oxidant solution, comprising a high percentage of water, an acid (e.g., for etching metal components) and an oxidant (e.g., for oxidizing the metal components). Additional components can be added to the dilute acid oxidant to further improve the wet process. The dilute acid oxidant solution can minimize damage to semiconductor devices incorporating metal gate electrodes, together with lower cost and waste disposal. In addition, the dilute acid oxidant solution can process, e.g., etching and cleaning, the metal gate features in an effective, predictable, and repeatable manner.

In some embodiments, the present invention discloses a method to fabricate a metal gate electrode, comprising selectively etching a first layer with respect to a second layer of the gate electrode, utilizing a dilute sulfuric peroxide solution. The first layer comprises a first material, and the second layer comprises a second material, which is different from the first material. The present dilute sulfuric peroxide solution can etch the first material with respect to the second material to form the metal gate electrode, removing the first material without or with minimum effect on the second material. For example, the selective etching process can form an undercut of the first material with respect to the second material; or can clean the first material from the second material. The dilute sulfuric peroxide solution can comprise at least 50%, 60%, 70%, or preferably at least 80% by weight of water, a sulfuric acid component of less than 30%, 15% or 10% by weight, and a hydrogen peroxide component of less than 10%, 20% or 30% by weight, with optionally less than 100 ppm or 30 ppm ozone. In some embodiments, the dilute sulfuric peroxide solution further comprises less than 100 ppm of hydrofluoric acid.

In some embodiments, the first material comprises a metal, such as titanium nitride, tungsten, or aluminum, and the second material comprises at least one of a semiconductor material, such as polycrystalline silicon or germanium, or an oxide, such as silicon dioxide or a high-k oxide. In some embodiments, the first material comprises TiN, and the second material comprises a metal. In some embodiments, the first material comprises a polymer, and the second material comprises at least one of a semiconductor material or an oxide.

In some embodiments, the dilute acid oxidant solution comprises at least 50% by weight of water, preferably deionized water. The dilute acid oxidant solution also more preferably comprises at least 80% by weight of water. The high percentage of water in the dilute acid oxidant solution can be environmentally safer and more cost effective.

The primary components in a dilute acid oxidant solution are an acid and an oxidant, for example, sulfuric acid and hydrogen peroxide, often referred to as dilute sulfuric peroxide (DSP). The acid can be any acid, and preferably a sulfuric acid. The amount of acid is lower than that of the water, forming a dilute acid solution for safe handling and low cost processing. The percentage of acid in the dilute acid oxidant solution can be less than 30% or 15% by weight, and more preferably less than 10%. During wet processing, the acid is not significantly consumed, and thus the acid concentration tends to remain constant until the process is completed.

The oxidant component can be any oxidizing agent, which is a chemical compound that can readily transfer oxygen atoms, or a substance that gains electrons in a redox chemical reaction. The oxidant can be a liquid oxidant, such as hydrogen peroxide, a gaseous oxidant, such as ozone, or a combination of multiple oxidant chemicals. In the dilute acid oxidant, the percentage of oxidant, for example, hydrogen peroxide, is preferably less than 20% by weight of the solution, and more preferably less than 10%. Dissolved gaseous oxidant, such as ozone, is preferably less than 100 ppm, and more preferably less than 30 ppm. In some embodiments, both oxidants of hydrogen peroxide and ozone can be included.

In some embodiments, the dilute acid oxidant further comprises other additives, such as hydrofluoric acid (HF) to improve the etch rate with improved control and cleaner metal gate structures. The dilute sulfuric peroxide solution with hydrofluoric acid additive is sometimes referred to a dilute sulfuric peroxide plus (DSP+). The amount of hydrofluoric acid additive is small, preferably less than 100 ppm, for example, in the range of about 5 ppm to about 20 ppm. The small amount of HF can be depleted over time, which reduces the solution effectiveness, thus an HF replenishing process can be implemented to maintain a relatively constant level of HF concentration. Other chemicals can be used instead of hydrofluoric acid, such as fluorine ion containing chemicals or fluorine ion releasing chemicals, such as fluorosulfuric acid (HSO₃F or SO₂F₂), which release hydrofluoric acid and fluorine ions.

In some embodiments, the present invention discloses a wet process utilizing the described dilute acid oxidant in the fabrication of metal gate features of semiconductor devices and integrated circuits. The wet process can be an etch process with high selectivity and controllability with respect to metal containing features and residues, allowing patterning and cleaning of the metal gate electrodes. For example, the present wet process can etch selectively a first material with respect to a second material, removing the first material without or with minimum effect on the second material.

In some embodiments, the present invention discloses a method to fabricate a device, comprising forming a multilayer metal gate electrode over a gate dielectric layer on a substrate, and patterning the multilayer metal gate electrode. The multilayer metal gate electrode can comprise a metal-containing layer such as TiN and a conductor layer such as poly silicon. The gate dielectric layer can comprise a high-k material.

The multilayer metal gate electrode can be patterned, for example, by a plasma etch process, to expose a sidewall of the metal-containing layer, which then can be selectively etched in a dilute sulfuric oxidant solution to form an undercut of the metal-containing layer. The dilute sulfuric oxidant solution can comprise at least 50% to 80% by weight of water, a sulfuric acid component of less than 30% to less than 10% by weight, and an oxidant component, which can comprise hydrogen peroxide of less than 10% to less than 30% by weight, or ozone with less than 100 ppm to less than 30 ppm. In some embodiments, the dilute sulfuric peroxide solution further comprises less than 100 ppm of hydrofluoric acid.

The present dilute sulfuric oxidant solution can selectively etch the metal-containing layer of the metal gate electrode to form an undercut with respect to the gate conductor layer. In some embodiments, gate dielectric layer can also be selectively etched, in addition to the metal-containing layer, with respect to the gate conductor layer. The undercut of the metal-containing layer can be controlled to achieve a desired profile of the undercut, such as a straight recess of the metal-containing layer.

In some embodiments, the patterning process of the multilayer metal gate electrode can generate organic polymer coating the metal gate electrode layer, which can be cleaned with the selective wet etch process comprising dilute sulfuric peroxide solution. The dilute sulfuric peroxide solution can selectively clean the organic polymer with respect to the metal gate electrode before the undercut formation process.

In some embodiments, the present wet process is performed to selectively etch metal components with respect to semiconductor, oxide or dielectric components. The metal components can comprise metal elements, such as aluminum, titanium or tungsten, or can comprise metal alloys or compounds, such as titanium nitride or tantalum nitride. The semiconductor components can comprise silicon or germanium, polycrystalline silicon or germanium, doped silicon or germanium. The oxide or dielectric components can comprise silicon dioxide, high-k oxide or dielectric such as hafnium oxide, aluminum oxide, or Ba—Sr—Ti—O (BST).

These two components can be incorporated in a metal gate structure of a semiconductor device. For example, a metal layer, such as a TiN layer, can be used in a metal gate electrode structure. A semiconductor layer, such as a doped poly silicon, can be used as a gate conductor layer in a metal gate electrode structure. A dielectric layer, such as silicon dioxide or high-k dielectric, can be used as a gate dielectric layer in a metal gate electrode structure. The wet process comprises selective etching of a metal-containing layer in a metal gate electrode with respect to at least one of the remaining layers, such as a gate dielectric layer or a gate conductor layer. The selective etching process can pattern the metal gate structure, such as etching the metal gate layer stopping on the date dielectric, or undercutting the metal layer with respect to the gate conductor layer.

In some embodiments, the present wet process is performed to selectively etch a metal component with respect to another metal component. These two different metal components can be two different metal-containing layers in a metal gate structure of a semiconductor device. For example, a first metal-containing layer, such as a TiN layer, can be disposed next to a gate dielectric layer to control the work function of the device. A second metal-containing layer, such as a tungsten, aluminum, or titanium layer, can be disposed on the first metal-containing layer to improve the conduction between devices. The wet process comprises selective etching of the first metal-containing layer in a metal gate electrode with respect to the second metal-containing layer, for example, allowing control of device structure for better device performance.

In some embodiments, the present wet process is performed to selectively clean polymer component with respect to a semiconductor or a dielectric component. During the patterning of a metal gate electrode, polymer is generated and then re-attached to the metal gate structure. The polymer can be an organic polymer, and can comprise trace amount of metal, for example, from the metal layer. The wet process can comprise selective etching of the generated polymer, without or with minimum damage to the metal gate electrode. The present dilute acid oxidant can have high etch rate for polymer, together with high etch rate for metal components, thus can effectively clean metal contaminated polymer generated from an etching of metal gate layer.

In some embodiments, the present invention discloses a wet process utilizing the above-described dilute acid oxidant to form a metal gate electrode with minimum damage, cleaned structure, and high controllability. The present invention further discloses semiconductor devices and integrated circuits utilizing the fabricated metal gate electrode.

In some embodiments, the present invention discloses a semiconductor device comprising a multilayer metal gate electrode with a straight undercut. The multilayer metal gate electrode comprises a metal-containing layer such as TiN and a conductor layer such as poly silicon, formed over a gate dielectric layer disposed on a substrate. The metal-containing layer further comprises a straight recess, forming the undercut with respect to the conductor layer. The gate dielectric layer can comprise a high-k material. In some embodiments, the gate dielectric layer can also be selectively etched to form an undercut.

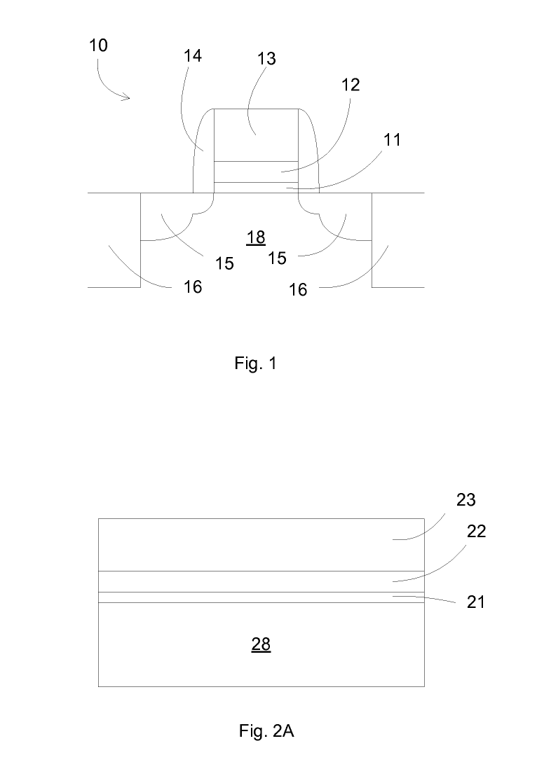

FIG. 1 illustrates a metal gate electrode device according to some embodiments of the present invention. The metal gate device 10 can be incorporated in integrated circuits, further comprising interconnects for connecting multiples devices. The device 10 is fabricated on a substrate 18, which is preferably single crystal silicon, although other substrates can be used, such as glass substrates, silicon-germanium substrates, or GaAs substrates. A metal gate electrode is fabricated on the substrate 18, comprising a gate dielectric layer 11, a metal gate layer 12 over the gate dielectric layer, and a gate conductor layer 13 over the metal gate layer. The device 10 is isolated from other devices by isolation regions 16, such as shallow trench isolation or local oxidation of silicon (LOCOS) isolation. The device 10 also comprises spacers 14 and source and drain regions 15. Other components can be included, such as n or p well region, depending on the type of the semiconductor devices.

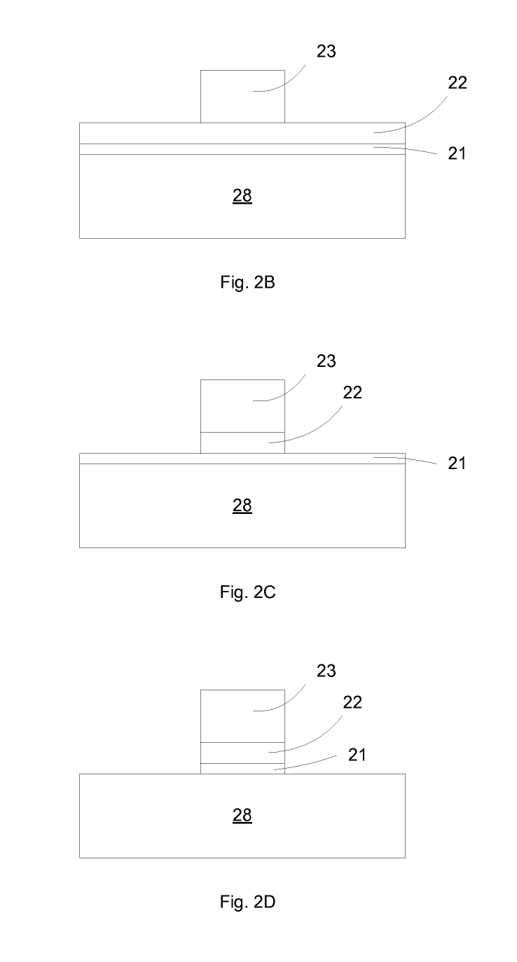

FIGS. 2A-2D illustrates a fabrication sequence for a metal gate electrode according to some embodiments of the present invention. In FIG. 2A, blanket layers of gate dielectric 21, metal gate layer 22 and gate conductor layer 23 are deposited on a substrate 28. The substrate 28 can be previously processed, for example, to form device well and isolation regions. The structure shown is exemplary, and other configurations can be used, such as a single metal gate layer instead of a metal gate layer 22 and a gate conductor layer 23, and a gate dielectric layer stack comprising a high-k dielectric layer on a silicon dioxide pedestal layer instead of a single gate dielectric layer 21.

The gate dielectric layer 21 can comprise any dielectric material, such as silicon dioxide, silicon oxynitride, high-k dielectric (such as hafnium oxide, or hafnium silicon oxynitride), or a combination of layers. Thin gate dielectric is desirable to improve the performance characteristics of semiconductor devices. In some embodiments, the thickness of the gate dielectric is less than 10 nm, and preferably less than 5 nm. The gate dielectric layer 21 can be formed by deposition, thermal growth, or a combination of both. For example, a silicon dioxide pedestal layer can be grown on a silicon substrate, and a high-k dielectric is deposited on the silicon dioxide pedestal layer.

Disposed on the gate dielectric layer 21 is a metal gate layer 22 together with a gate conductor layer 23. Alternatively, the gate conductor layer 23 can be omitted, leaving only a metal gate layer 22. The metal gate layer 22 typically comprises a first metal, and the gate conductor 23 can either comprise a poly silicon or a second metal, different from the first metal. In some embodiments, the metal gate layer 22 is a metal-containing layer, having a metal component together with other combination of materials.

The metal gate layer 22 preferably comprises a refractory metal or a nitride of a refractory metal, such as titanium nitride. Alternatively, the metal gate layer 22 can comprise other metal, including WN, TaN, Mo, RuO₂, or NiSi. The thickness of the metal gate layer 22 can be less than 20 nm with the gate conductor layer, or can be less than 200 nm without a gate conductor layer.

The gate conductor layer 23 can comprise silicon, such as doped poly silicon or amorphous silicon. Alternatively, the gate conductor layer 23 can comprise a second metal, different from the first metal in the metal gate layer 22. In addition, the gate conductor can be omitted. The thickness of the gate conductor can be less than 200 nm.

The metal gate layer 22 and gate conductor layer 23 can be formed by any methods, such as atomic layer deposition (ALD), physical vapor deposition (PVD), chemical vapor deposition (CVD), and spin coating.

FIGS. 2B-2D show a sequence of patterning for the gate conductor layer 23, the metal gate 22, and the gate dielectric 21, respectively. Any patterning process can be used, for example, lithography patterning process using photoresist mask and dry or wet etching. The layers can be patterned using a plasma etch process or a wet etch process.

In some embodiments, the gate conductor layer 23 and a portion of the metal gate layer 22 are patterned using a plasma etch. The metal gate layer 22, or the remaining portion of the metal gate layer 23 after the plasma etch, can be subjected to the present wet process utilizing a dilute acid oxidant solution, which is highly selective to etch the metal gate layer 22 without damaging the gate dielectric layer 21. The gate dielectric can be removed by another etch process, such as a wet etch using hydrofluoric acid for etching silicon dioxide.

After the completion of the metal gate electrode, the substrate can be further processed to form active devices and circuits. For example, additional steps of implanting dopants to form source and drain structures, forming gate spacers, and shallow junctions. Interconnect metal lines can be included, connecting a plurality of active devices to form an integrated circuit.

In some embodiments, the present invention discloses a wet process utilizing the above-described dilute acid oxidant to form metal gate electrode configurations with high controllability. The present invention further discloses semiconductor devices and integrated circuits utilizing the fabricated metal gate electrode.

High vertical electric field in the drain extension region can generate tunneling leakage current in MOS field-effect transistors, especially for devices with thin gate dielectric. In a metal gate device, the thickness of the metal gate electrode can be selected to achieve a desired work function and threshold voltage. However, thicker metal gate electrode can induce higher electric field, leading to higher leakage current. To reduce the leakage current without changing the overall thickness of the metal gate layer, an undercut profile of the metal gate electrode can be designed with lower electric field to the drain region.

In some embodiments, the present invention discloses methods and devices using the above-described dilute acid oxidant solution, in the construction of desired profiles for a metal gate electrode of a semiconductor device. A wet process utilizing the dilute acid oxidant solution can form an undercut of a metal-containing layer in a metal gate electrode.

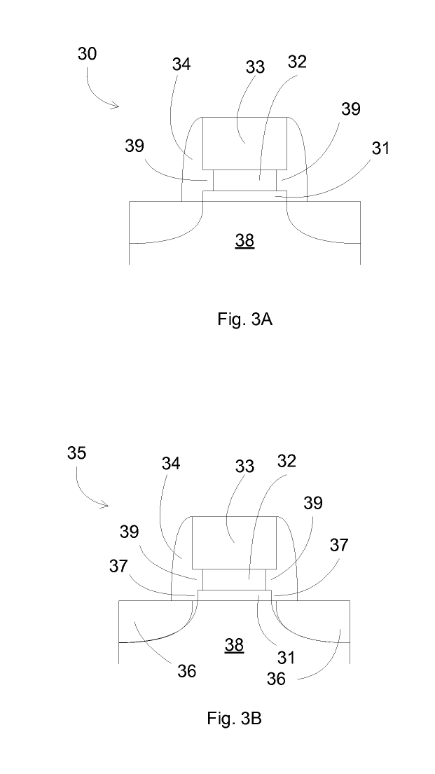

FIGS. 3A-3B illustrate metal gate electrode devices having an undercut profile according to some embodiments of the present invention. In FIG. 3A, the metal gate device 30 can be incorporated in integrated circuits, further comprising interconnects for connecting multiples devices. The device 30 is fabricated on a substrate 38, comprising a gate dielectric layer 31, a metal gate layer 32 over the gate dielectric layer, and a gate conductor layer 33 over the metal gate layer. The metal gate structure is protected by spacers 34. There can be silicide regions (not shown) on the gate conductor layer 33 for improving contact resistance. The device 30 can be similar to the above-described metal gate device, with similar configurations, materials and processing.

The metal gate layer 32 further comprises a recess 39 (a lateral undercut) in its sidewalls, tailored to reduce a leakage current of the device, for example, by reducing the electric field to the source and drain regions. In some embodiments, the spacers 34 can fill in the lateral undercuts 39. The device shown is an exemplary planar device configuration, and other device configurations are also within the scope of the present invention, such as tri-gate transistor configurations, fin-FET configurations, or different types of transistors or devices.

In some embodiments, the present invention discloses a metal gate layer having an undercut profile designed to reduce a leakage current of the device. The undercut profile can be fabricated by a wet etch process utilizing the above-described dilute acid oxidant solution. Since the dilute acid oxidant solution can be highly selective with good etch rate controllability, desired profiles for the undercut can be achieved. For example, a straight undercut 39 for the metal gate layer 32 can be fabricated using the dilute acid oxidant. The undercut 39 can reduce the electric field between the metal gate and the source/drain regions, resulting in reduced off-state leakage current.

In FIG. 3B, the device 35 further comprises undercut 37 for the gate dielectric 31. The gate dielectric undercut 37 and the metal gate undercut 39 can be similar, or one can be larger or smaller than the other. The source/drain profiles 36 can be designed to achieve a desired performance.

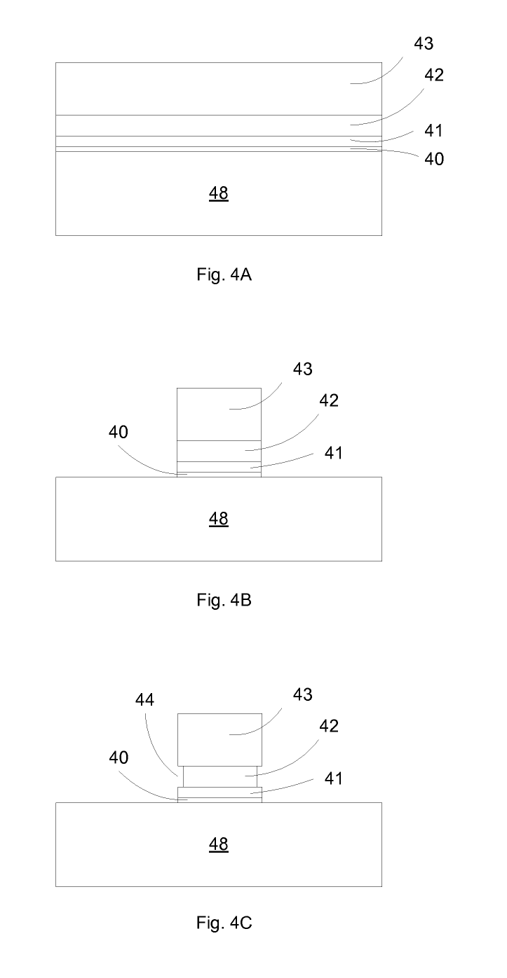

FIGS. 4A-4C illustrate an exemplary fabrication sequence for a metal gate with undercut according to some embodiments of the present invention. In some embodiments, the device metal gate structure can be formed differently.

In FIG. 4A, blanket layers of silicon dioxide pedestal 40, high-k gate dielectric 41, metal gate layer 42 and gate conductor layer 43 are deposited on a substrate 48. The substrate 48 can be previously processed, for example, to form device well and isolation regions. The structure shown is exemplary, and other configurations can be used, such as a single metal gate layer instead of a metal gate layer 22 and a gate conductor layer 23, and a single gate dielectric layer stack instead of a silicon dioxide layer 40 and a high-k gate dielectric layer 41.

The high-k dielectric layer 41 can comprise a high k material such as hafnium oxide, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, and lead zinc niobate.

Disposed on the gate dielectric layer 41 is a metal gate layer 42 together with a gate conductor layer 43. Alternatively, the gate conductor layer 43 can be omitted, leaving only a metal gate layer 42. The metal gate layer 42 typically comprises a first metal, and the gate conductor 43 can either comprise a poly silicon or a second metal, different from the first metal. In some embodiments, the metal gate layer 42 is a metal-containing layer, having a metal component together with other combination of materials.

The metal gate layer 42 for NMOS devices can comprise a metal, such as hafnium, zirconium, titanium, tantalum, aluminum, or their alloys. The metal gate layer 42 for PMOS devices can comprise ruthenium, palladium, platinum, cobalt, nickel, and conductive metal oxides. The metal gate layer 42 preferably comprises a refractory metal or a nitride of a refractory metal, such as titanium nitride.

The gate conductor layer 23 can comprise any suitable conductive material, such as poly silicon, tungsten, aluminum, titanium, titanium nitride.

In FIG. 4B, the layers are patterned, for example, by a photo lithography process with dry or wet etching. In some embodiments, the metal gate layer 42 can be patterned using a combination of plasma etch and a wet process utilizing a dilute acid oxidant solution, which is highly selective to etch the metal gate layer 42 without damaging the gate dielectric layer 41.

In FIG. 4C, after patterning the metal gate electrode, a wet etch using the above-described dilute acid oxidant can be performed to form undercuts 44 on the metal gate layer 42. The profile and size of the undercuts 44 can be controlled to achieve a device performance, such as minimum leakage current of the device. Optionally, the gate dielectric layers can be recessed (not shown). In some embodiments, the metal gate layer 42 can be selectively etched by a combination of dry etch and dilute acid oxidant wet etch to form the lateral undercuts 44. The dilute acid oxidant solution, such as dilute sulfuric peroxide solution, can etch the metal gate layer without damaging the metal gate electrode. The wet process is preferably performed at temperatures less than 60 C, followed by a water rinse, for example at room temperature or preferably between 15 and 60 C. The etch rate is related to the process temperature, with higher etch rates at higher temperatures.

After the completion of the metal gate electrode, the substrate can be further processed to form active devices and circuits. For example, additional steps of implanting dopants to form source and drain structures, forming gate spacers, and shallow junctions. Interconnect metal lines can be included, connecting a plurality of active devices to form an integrated circuit.

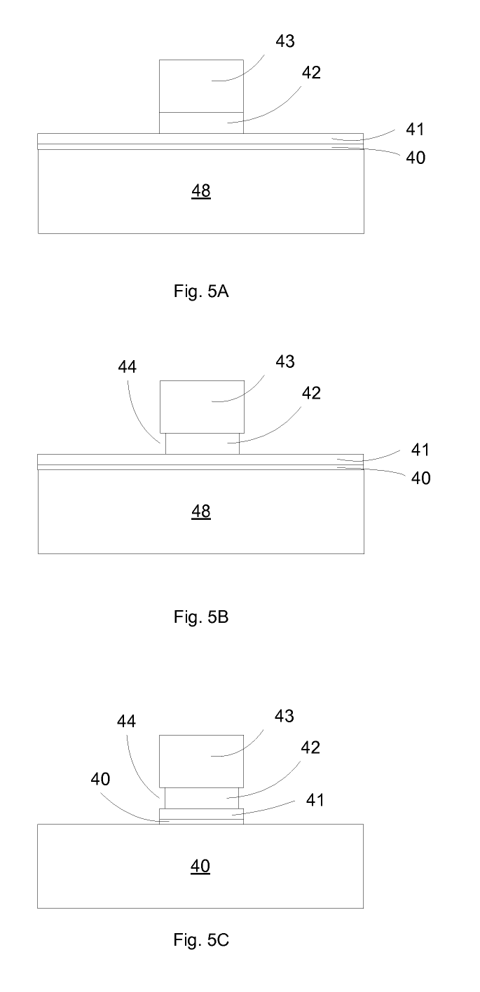

In some embodiments, the gate dielectric layers 40 and 41 can be patterned after forming the lateral undercuts 44. FIGS. 5A-5C illustrate an exemplary sequence for a metal gate with undercut according to some embodiments of the present invention. In such embodiments, the gate conductor layer 43 and the metal gate layer 42 are patterned, and then subjected to the dilute acid oxidant solution to form the undercuts 44. The gate dielectric layers 40 and 41 can then be patterned, and optionally recessed to form dielectric undercuts, in addition to or in place of the metal gate layer undercuts.

In an exemplary embodiment, a wet process utilizes a solution of dilute acid oxidant, which comprises a mixture of 7% by weight sulfuric acid, 7% by weight hydrogen peroxide, and 100 ppm HF. After etching the gate conductor layer 43 and the metal gate layer 42, for example through a photoresist mask (not shown), the semiconductor wafer is immersed or sprayed with the dilute acid oxidant solution for a specific amount of time to achieve a desired undercut profile 44 then rinsed and dried. The processing temperature is about 45 C, including the temperature of the solution, the temperature of the rinse water and/or the temperature of the wafer. Typical etch rates of TiN using the dilute acid oxidant solution at temperature between 45 C and 55 C are between 1-3 nm/min with very high selectivity as compared to other materials such as poly silicon or silicon oxide, and therefore the etch solution can enable a controllable etching of TiN in a metal gate electrode without damaging other materials in the gate. For a device width of about 40 nm, an undercut of about 3 nm can be achieved.

In some embodiments, the present invention discloses a cleaning process for a metal gate electrode using a dilute acid oxidant, preferably the above-described dilute acid oxidant, for example, to efficiently remove contaminants formed around a metal gate structure. During the device fabrication process, the substrate is exposed to various environments, which comprise multiple potential sources of contamination. For example, chemicals used in etching or deposition processes can leave deposit on gate structures and on the substrate surfaces as particulates or polymer residue contaminants. Further, in metal gate fabrication processes, the contaminant can be polymer residue species such as O, C, Si, and metal-containing polymer contaminants. In some embodiments, high-k contaminant on the semiconductor surface can also be generated during high-k dielectric processes, such as a high-k anneal following a high-k dielectric deposition. In some embodiments, the plasma etch does not etch completely the metal gate electrode, for example, to prevent over-etching the underlying gate dielectric. The incomplete-etched metal gate layer can be considered as contaminants or residues, and can be cleaned by the present dilute acid oxidant solution.

The present cleaning process can remove the contaminants, including the polymer residues, the metal-containing polymer residues, and the high-k contaminants, while preserving the characteristics of the metal gate structure. The cleaning process uses simple and common chemistries with high selectivity for effectively cleaning unwanted polymer residues, retaining control of critical dimension, and avoiding damage to the metal gate electrode.

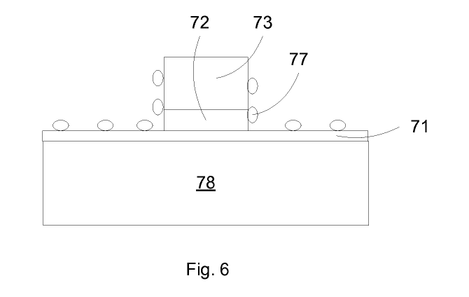

FIG. 6 illustrates a schematic representation of exemplary contaminants on a metal gate electrode after a plasma etch process according to some embodiments of the present invention. A gate conductor 73 is disposed on a metal gate layer 72, which is disposed on a gate dielectric 71 over a substrate 78. The gate conductor 73 and the metal gate layer 72 are patterned, for example, by a plasma etch process. After the plasma etch, contaminants 77 are generated, coating the sidewalls and the planar surface of the substrate 78. In some cases, the metal gate layer 72 might not be completely and cleanly etched, forming a non-vertical profile. In addition, the plasma etch process may form residues, including generated residues on the sidewalls and on the substrate surface (e.g., polymer, metal-containing polymer, and high-k contaminants), together with incomplete etched materials from the metal gate electrode.

In some embodiments, the present invention discloses methods and devices fabricated from the methods, for cleaning a metal gate electrode of a semiconductor device using a dilute acid oxidant solution. The selective cleaning process can be achieved by a higher etch rate of the polymer as compared to the etch rate of the metal gate electrode.

In some embodiments, the cleaning process can be used in conjunction with an undercut etching process, thus the metal gate electrode can undergo a cleaning process and an undercut etching process at a same time (or sequentially in a same etching operation). The present dilute acid oxidant can be very effective, resulting in a clean metal gate electrode with controlled undercut profile. Alternatively, the metal gate electrode can be cleaned without forming the undercuts.

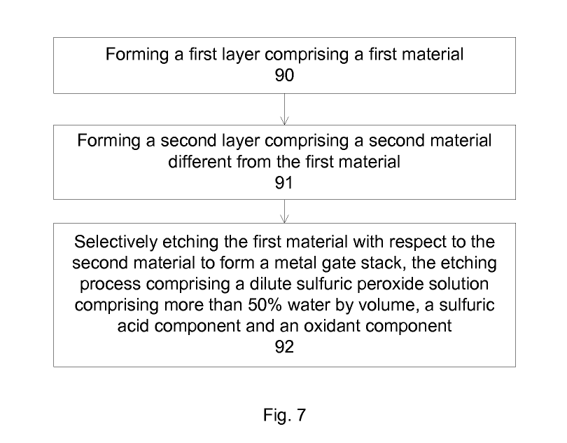

FIG. 7 illustrates an exemplary process flow for a selective etching process according to some embodiments of the present invention. The selective etching process selectively etches a first material with respect to a second material using a dilute acid oxidant solution, such as the above-described dilute sulfuric peroxide solution. The selective etching process can also be a selective cleaning process, cleaning residues and any incomplete etching product. Operation 90 forms a first layer comprising a first material, preferably over a substrate. Operation 91 forms a second layer comprising a second material different from the first material. Operation 92 selectively etches the first material with respect to the second material to form a metal gate stack using a dilute acid oxidant solution. In some embodiments, the dilute acid oxidant solution comprises a dilute sulfuric peroxide solution comprising more than 50% water by weight, a sulfuric acid component and a hydrogen peroxide component. The dilute sulfuric peroxide solution can further comprise a small amount of hydrofluoric acid. In some embodiments, the dilute sulfuric peroxide solution comprises the composition and processes as described above. The etching process can be performed at a desired process temperature, preferably less than 60 C. An optional water rinsing step can be added after the selective etching step.

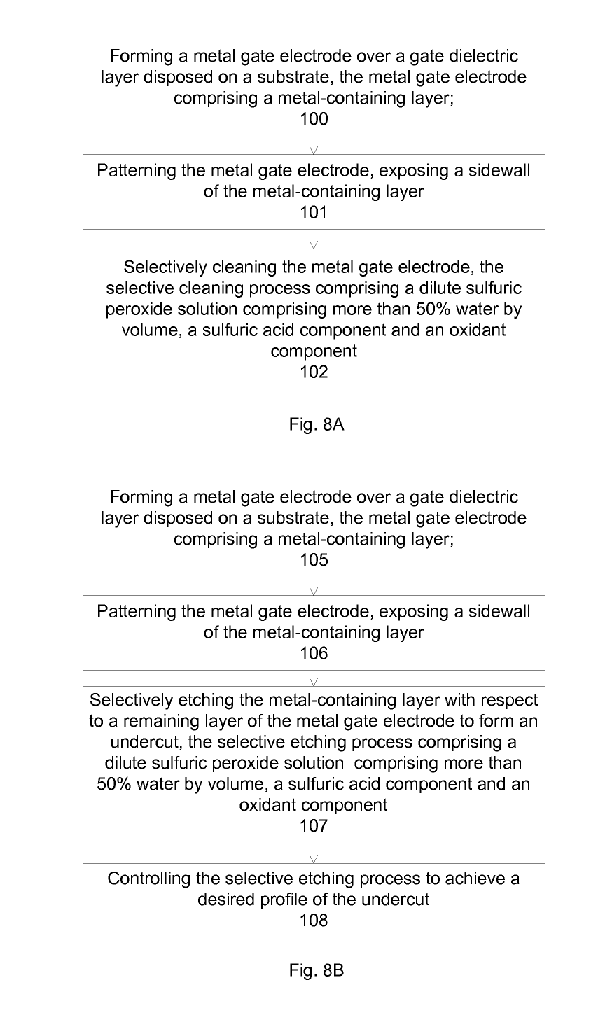

FIG. 8A illustrates an exemplary process flow for a metal gate electrode fabrication process according to some embodiments of the present invention. Operation 100 forms a metal gate electrode over a gate dielectric layer disposed on a substrate, the metal gate electrode comprising a metal-containing layer. Operation 101 patterns the metal gate electrode, exposing a sidewall of the metal-containing layer. The patterning process preferably comprises a plasma etching process, which can generate contaminants, such as organic polymer contaminants, metal-containing contaminants from the metal-containing layer, or high-k contaminants from a high-k gate dielectric layer. Operation 102 performs a selective clean of the metal gate electrode, for example, by cleaning the contaminants remaining after the patterning process, and/or completing the patterning process by cleaning the metal-containing layer which still remains after the patterning process. In some embodiments, the patterning process does not completely remove the metal-containing layer, for example, to avoid damaging the gate dielectric layer. The selective cleaning process can then complement the patterning process, effectively forms a two step patterning process with a cleaning capability, completing the etching of the metal-containing layer while removing all contaminants surrounding the metal gate electrode.

In some embodiments, the selective clean process utilizing a dilute acid oxidant solution, preferably comprising a dilute sulfuric peroxide solution having more than 50% water by weight, a sulfuric acid component and a hydrogen peroxide component. The dilute sulfuric peroxide solution can further comprise a small amount of hydrofluoric acid. In some embodiments, the dilute sulfuric peroxide solution comprises the composition and processes as described above. The cleaning process can be performed at a desired process temperature, preferably less than 60 C. An optional water rinsing step can be added after the cleaning step. In some embodiments, a selectively etch is optionally added to selectively etch the metal-containing layer with respect to a remaining layer of the metal gate electrode to form an undercut. In some embodiments, the selective etch is performed using a same dilute acid oxidant as in the cleaning step. The selective etch and the cleaning process can be performed separately. Alternatively, the selective etch can be performed in conjunction with the cleaning process, effectively combining the two processes into one longer process step. An optional water rinsing step can be added after the selective etching step.

FIG. 8B illustrates another exemplary process flow for a metal gate electrode fabrication process according to some embodiments of the present invention. Operation 105 forms a metal gate electrode over a gate dielectric layer disposed on a substrate, the metal gate electrode comprising a metal-containing layer. Operation 106 patterns the metal gate electrode, exposing a sidewall of the metal-containing layer. Operation 107 selectively etches the metal-containing layer with respect to a remaining layer of the metal gate electrode to form an undercut using a dilute acid oxidant solution. In some embodiments, the dilute acid oxidant solution comprises a dilute sulfuric peroxide solution comprising more than 50% water by weight, a sulfuric acid component and a hydrogen peroxide component. The dilute sulfuric peroxide solution can further comprise a small amount of hydrofluoric acid. In some embodiments, the dilute sulfuric peroxide solution comprises the composition and processes as described above. The selective etching process can be performed at a desired process temperature, preferably less than 60 C. An optional water rinsing step can be added after the etching step. Operation 108 is optional, performs to control the selective etching process to achieve a desired profile of the undercut.

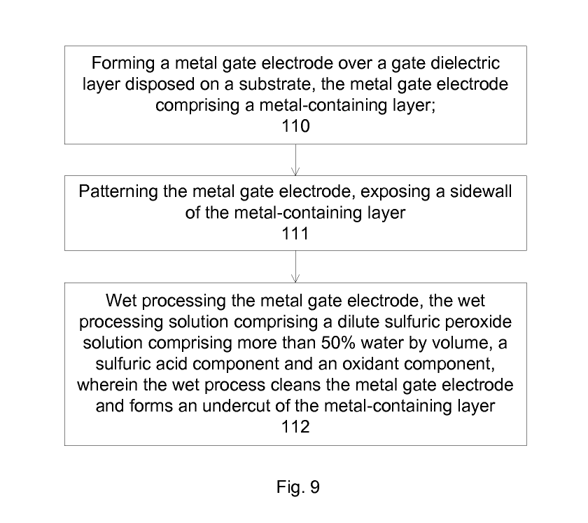

FIG. 9 illustrates another exemplary process flow for a metal gate electrode fabrication process according to some embodiments of the present invention. Operation 110 forms a metal gate electrode over a gate dielectric layer disposed on a substrate, the metal gate electrode comprising a metal-containing layer. Operation 111 patterns the metal gate electrode, exposing a sidewall of the metal-containing layer. Operation 112 performs a wet process of the metal gate electrode using a dilute acid oxidant solution. In some embodiments, the dilute acid oxidant solution comprises a dilute sulfuric peroxide solution having compositions and processes as described above. The wet process can be a clean process, an etch process, or a combination of the clean and etch process. The wet process can be performed at a desired process temperature, preferably less than 60 C. An optional water rinsing step can be added after the cleaning step.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method to fabricate an electrode, comprising
forming a first layer on a substrate, the first layer comprising a first material;
forming a second layer on the first layer, the second layer comprising a second material wherein the second material is different from the first material; and
selectively etching the first layer, the selective etching process comprising a solution that comprises sulfuric acid, hydrogen peroxide, and more than 50% water by weight.

2. A method as in claim 1, wherein the solution comprises at least 80% water by weight.

3. A method as in claim 1, wherein the selective etching process further comprises forming an undercut of the first material.

4. A method as in claim 1, wherein the selective etching process further comprises cleaning the second layer.

5. A method as in claim 1, wherein the solution further comprises less than 100 ppm hydrofluoric acid.

6. A method as in claim 1, wherein one of
the first material comprises a metal and the second material comprises at least one of silicon, germanium or an oxide;
the first material comprises TiN and the second material comprises a metal; or
the first material comprises a polymer and the second material comprises at least one of silicon, germanium or an oxide.

7. A method to fabricate a device, comprising
forming a multilayer metal gate electrode over a gate dielectric layer disposed on a substrate, the multilayer metal gate electrode comprising a metal-containing layer and a conductor layer;
patterning the multilayer metal gate electrode, and thereby exposing a sidewall of the metal-containing layer;
selectively etching the metal-containing layer to form an undercut, the selective etching process comprising a solution that comprises more than 50% water by weight, sulfuric acid and an oxidant.

8. A method as in claim 7, wherein the solution comprises at least 80% water by weight.

9. A method as in claim 7, wherein the metal gate electrode comprises a metal-containing layer of TiN and a conductor layer of poly silicon, and wherein the gate dielectric layer comprises a high-k material.

10. A method as in claim 7, further comprising
selectively etching the gate dielectric layer.

11. A method as in claim 7, further comprising
controlling the selective etching process to achieve a desired profile of the undercut.

12. A method as in claim 7, wherein the oxidant component comprises at least one of hydrogen peroxide or ozone.

13. A method as in claim 12, wherein the solution comprises less than 10% by weight of hydrogen peroxide.

14. A method as in claim 12, wherein the solution comprises less than 100 ppm of ozone.

15. A method as in claim 7, wherein the solution further comprises less than 100 ppm of hydrofluoric acid.

16. A method as in claim 7, wherein the solution comprises less than 10% by weight of sulfuric acid.

17. A method as in claim 7, wherein the patterning process generates an organic polymer coating on the metal gate electrode layer, the method further comprising
selectively cleaning the organic polymer before the selective etching process, the selective cleaning process comprising the solution.

18. A semiconductor device, comprising
a multilayer metal gate electrode formed over a gate dielectric layer disposed on a substrate, the multilayer metal gate electrode comprising a metal-containing layer and a conductor layer;
an undercut of the metal-containing layer with respect to the conductor layer, the undercut comprising a straight recess of the metal-containing layer.

19. A method as in claim 18, wherein the metal gate electrode comprises a metal-containing layer of TiN and a conductor layer of poly silicon, and wherein the gate dielectric layer comprises a high-k material.

20. A device as in claim 18, further comprising
an undercut of the gate dielectric layer.
